(19) United States
(12) Patent Application Publication
(10) Pub. No.: US 2024/0182498 A1
(43) Pub. Date: Jun. 6, 2024

(54) DISILYLAMINE PRECURSORS AND RELATED METHODS

(71) Applicant: ENTEGRIS, INC., Billerica, MA (US)

(72) Inventors: SeongCheol Kim, Suwon-si (KR); YeRim Yeon, Suwon-si (KR); SangJin Lee, Suwon-si (KR); DaHye Kim, Suwon-si (KR); MinSeok Ryu, Namdong-gu (KR); KieJin Park, Gwacheon-si (KR)

(21) Appl. No.: 18/513,001

(22) Filed: Nov. 17, 2023

Related U.S. Application Data
(60) Provisional application No. 63/427,354, filed on Nov. 22, 2022.

(51) Int. Cl. C07F 7/10; C23C 16/22; C23C 16/455

(52) U.S. Cl. CPC C07F 7/10; C23C 16/22; C23C 16/45553

(57) ABSTRACT

A composition comprises a disilylamine precursor. The disilylamine precursor comprises a functional group attached to a nitrogen atom of the dilsilylamine precursor. The functional group comprises an alkyl, an alkenyl, an alkynyl, a cycloalkyl, an aryl, or a benzyl. Related methods are provided, including a method for forming the disilylamine precursor and a method for vapor deposition.

### FIELD

The present disclosure relates to disilylamine precursors for vapor deposition processes and related methods.

### BACKGROUND

Vapor deposition processes use precursors. The precursors are vaporized and deposited on substrates as films.

### SUMMARY

Some embodiments relate to a precursor. In some embodiments, the precursor comprises a compound of the formula:

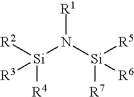

where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

Some embodiments relate to a method for forming a precursor. In some embodiments, the method comprises obtaining an amine compound. In some embodiments, the method comprises obtaining at least one silylhalide compound.

In some embodiments, the method comprises contacting the amine compound and the at least one silylhalide compound, so as to form the precursor. In some embodiments, the precursor is a compound of the formula:

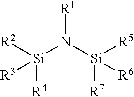

where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

Some embodiments relate to a method for vapor deposition. In some embodiments, the method comprises obtaining a precursor. In some embodiments, the precursor comprises a compound of the formula:

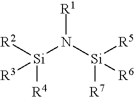

where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

In some embodiments, the method comprises vaporizing the precursor to obtain a vaporized precursor. In some embodiments, the method comprises contacting the vaporized precursor with a substrate, under vapor deposition conditions, so as to form a silicon-containing film on the substrate.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for forming a precursor, according to some embodiments.

FIG. 2 is a flowchart of a method for making a silicon-containing film, according to some embodiments.

FIG. 3 is a schematic diagram of a reaction scheme for forming a precursor, according to some embodiments.

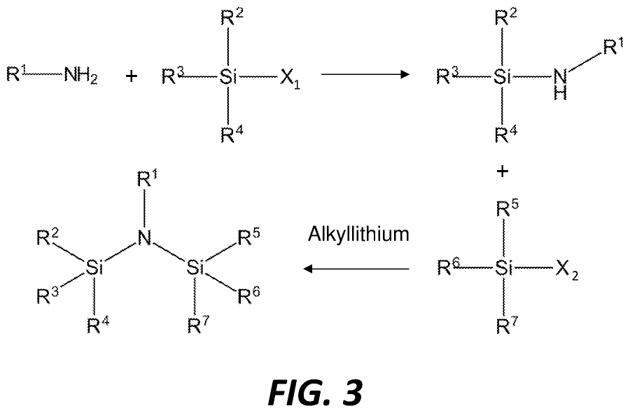

FIG. 4 is a schematic diagram of a reaction scheme for forming a precursor, according to some embodiments.

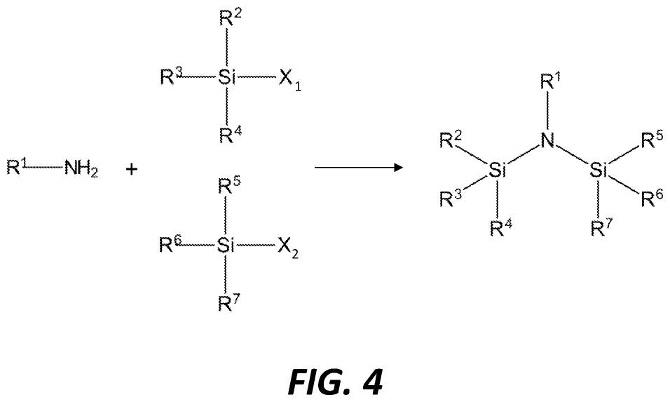

FIG. 5 is a proton nuclear magnetic resonance spectrum (¹H NMR) of a precursor, according to some embodiments.

FIG. 6 is a proton nuclear magnetic resonance spectrum (¹H NMR) of a precursor, according to some embodiments.

FIG. 7 is a proton nuclear magnetic resonance spectrum (¹H NMR) of a precursor, according to some embodiments.

FIG. 8 is a proton nuclear magnetic resonance spectrum (¹H NMR) of a precursor, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “alkyl” refers to a hydrocarbyl having from 1 to 30 carbon atoms. The alkyl may be attached via a single bond. An alkyl having n carbon atoms may be designated as a “Cn alkyl.” For example, a “Cs alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl may comprise, consist of, or consist essentially of, or may be selected from the group consisting of, at least one of a C₁-C₁₂ alkyl, a C₁-C₁₁ alkyl, a C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, a C₃-C₄ alkyl, or any combination thereof. In some embodiments, the alkyl is a linear C₁-C₄ alkyl. In some embodiments, the alkyl is a branched C₃-C₄ alkyl. In some embodiments, the alkyl may comprise, consist of, or consist essentially of, or may be selected from the group consisting of, at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, octyl, decyl, dodecyl, octadecyl, or any combination thereof. In some embodiments, the alkyl is substituted with one or more substituents.

As used herein, the term “alkenyl” refers to a hydrocarbyl having from 1 to 10 carbon atoms and at least one carbon-carbon double bond. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof. In some embodiments, the alkenyl is substituted with one or more substituents.

As used herein, the term “alkynyl” refers to a hydrocarbyl having from 1 to 10 carbon atoms and at least one carbon-carbon triple bond. Examples of alkynyl groups include, without limitation, at least one of ethynyl, propynyl, n-butynyl, n- pentynyl, 3-methyl-1-butynyl, n-hexynyl, methyl-pentynyl, or any combination thereof. In some embodiments, the alkynyl is substituted with one or more substituents.

As used herein, the term “cycloalkyl” refers to a non-aromatic carbocyclic ring having from 3 to 8 carbon atoms in the ring. In some embodiments, the cycloalkyl comprises a C₃-C₆ cycloalkyl. In some embodiments, the cycloalkyl comprises a C₃-C₅ cycloalkyl. In some embodiments, the cycloalkyl comprises a C₃-C₄ cycloalkyl. The term includes a monocyclic non-aromatic carbocyclic ring and a polycyclic non-aromatic carbocyclic ring. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof. In some embodiments, the cycloalkyl is substituted with one or more substituents.

As used herein, the term “aryl” refers to a monocyclic or polycyclic aromatic hydrocarbon. The number of carbon atoms of the aryl may be in a range of 5 carbon atoms to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. Examples of aryls include, without limitation, phenyl, biphenyl, napthyl, and the like. In some embodiments, the aryl comprises benzyl. In some embodiments, the aryl is substituted with one or more substituents.

Non-limiting examples of aryl include, without limitation, at least one of benzene, toluene, xylene (e.g., o-xylene, m-xylene, p-xylene), t-butyltoluene (e.g., o-t-butyltoluene, m-t-butyltoluene, p-t-butyltoluene), ethylmethylbenzene (e.g., 1-ethyl-4-methylbenzene, 1-ethyl-3-methylbenzene), 1-isopropyl-4-methylbenzene, 1-t-butyl-4-methylbenzene, mesitylene, pseudocumene, durene, methylbenzene, dimethylbenzene, trimethylbenzene, ethylbenzene, diethylbenzene (e.g., 1,4-diethylbenzene), triethylbenzene, propylbenzene, butylbenzene, iso-butylbenzene, sec-butylbenzene, t-butylbenzene, hexylbenzene, styrene, naphthalene, anthracene, phenanthrene, biphenyl, terphenyl, methylnaphthalene, biphenylene, dimethylnaphthalene, methylanthracene, 4,4′-dimethylbiphenyl, bibenzyl, diphenylmethane, any isomer thereof, or any combination thereof, and the like.

As used herein, the term “amine” refers to a functional group of formula —N(R^{a}R^{b}R^{c}), wherein each of R^{a}, R^{b}, and R^{c} is independently a hydrogen, an alkyl, an alkenyl, an alkynyl, a cycloalkyl, an aryl, or a benzyl, or two of Ra, Rb, and Rc are bonded to form a 3-membered cyclic ring to a 6-membered cyclic ring. In some embodiments, where at least one of R^{a}, R^{b}, or R^{c} is a hydrogen, the amine is a functional group of the formula: —NH(R^{b}R^{c}). In some embodiments, the term “amine” includes an amino, as defined herein. In some embodiments, the amine may comprise, consist of, or consist essentially of a primary amine, a secondary amine, a tertiary amine, or a quaternary amine. In some embodiments, the amine may comprise, consist of, or consist essentially of an alkyl amine, a dialkylamine, or a trialkyl amine. In some embodiments, the amine may comprise, consist of, or consist essentially of, or may be selected from the group consisting of, at least one of methyl amine, dimethylamine, ethylamine, diethylamine, isopropylamine, di-isopropylamine, butylamine, sec-butylamine, tert-butylamine, di-sec-butylamine, isobutylamine, di-isobutylamine, di-tert-pentylamine, ethylmethylamine, isopropyl-n-propylamine, or any combination thereof. Examples of the amines may include, without limitation, one or more of the following: primary amines, such as, for example and without limitation, methylamine, ethylamine, n-propylamine, isopropylamine, n-butylamine, sec-butylamine, isobutylamine, t-butylamine, pentylamine, 2-aminopentane, 3-aminopentane, 1-amino-2-methylbutane, 2-amino-2-methylbutane, 3-amino-2-methylbutane, 4-amino-2-methylbutane, hexylamine, 5-amino-2-methylpentane, heptylamine, octylamine, nonylamine, decylamine, undecylamine, dodecylamine, tridecylamine, tetradecylamine, pentadecylamine, hexadecylamine, heptadecylamine, and octadecylamine; secondary amines, such as, for example and without limitation, dimethylamine, diethylamine, dipropylamine, diisopropylamine, dibutylamine, diisobutylamine, di-sec-butylamine, di-t-butylamine, dipentylamine, dihexylamine, diheptylamine, dioctylamine, dinonylamine, didecylamine, methylethylamine, methylpropylamine, methylisopropylamine, methylbutylamine, methylisobutylamine, methyl-sec-butylamine, methyl-t-butylamine, methylamylamine, methylisoamylamine, ethylpropylamine, ethylisopropylamine, ethylbutylamine, ethylisobutylamine, ethyl-sec-butylamine, ethylamine, ethylisoamylamine, propylbutylamine, and propylisobutylamine; and tertiary amines, such as, for example and without limitation, trimethylamine, triethylamine, tripropylamine, tributylamine, tripentylamine, dimethylethylamine, methyldiethylamine, and methyldipropylamine. Examples of polyamines may include, without limitation, one or more of the following: ethylenediamine, propylenediamine, trimethylenediamine, tetramethylenediamine, 1,3-diaminobutane, 2,3-diaminobutane, pentamethylenediamine, 2,4-diaminopentane, hexamethylenediamine, heptamethylenediamine, octamethylenediamine, nonamethylenediamine, N-methylethylenediamine, N,N-dimethylethylenediamine, trimethylethylenediamine, N-ethylethylenediamine, N,N-diethylethylenediamine, triethylethylenediamine, 1,2,3-triaminopropane, hydrazine, tris(2-aminoethyl)amine, tetra(aminomethyl)methane, diethylenetriamine, triethylenetetramine, tetraethylpentamine, heptaethyleneoctamine, nonaethylenedecamine, and diazabicyloundecene. In some embodiments, the amine is substituted with one or more substituents.

In some embodiments, the polyamine compound comprises, consists of, or consists essentially of, or is selected from the group consisting of, at least one of ethylenediamine, propylenediamine, trimethylenediamine, triethylenediamine, methylpentanediamine, tetramethylenediamine, 1,3-diaminobutane, 2,3-diaminobutane, pentamethylenediamine, 2,4-diaminopentane, hexamethylenediamine, heptamethylenediamine, octamethylenediamine, nonamethylenediamine, 1,2,3-triaminopropane, hydrazine, tetra(aminomethyl)methane, or any combination thereof. In some embodiments, the polyamine compound comprises, consists of, consists essentially of, or is selected from the group consisting of, at least one of N-methylethylenediamine, N,N-dimethylethylenediamine, trimethylethylenediamine, N-ethylethylenediamine, N,N-diethylethylenediamine, triethylethylenediamine, or any combination thereof.

In some embodiments, the polyamine compound comprises, consists of, consists essentially of, or is selected from the group consisting of, at least one of tris(2-aminoethyl)amine, diethylenetriamine, triethylenetetramine, tetraethylenepentamine, heptaethyleneoctamine, nonaethylenedecamine, N′,N′-bis(2-aminoethyl)ethane-1,2-diamine, or any combination thereof. In some embodiments, the polyamine compound comprises at least one of 1,2-ethane diamine; 1,2-propane diamine; 1,3-propane diamine; 1,4-butane diamine; 1,6-hexane diamine; 2-methyl-1,5-pentane diamine; 2,2(4),4-trimethylhexanediamine; 2,2,4-trimethyl-1,6-hexanediamine; 2,4,4-trimethyl-1,6-hexanediamine; or any combination thereof.

As used herein, the term “contacting” refers to bringing into direct contact, or immediate or close proximity. In some embodiments, the contacting is sufficient to react two or more components. The term “contacting” includes, for example and without limitation, at least one of mixing, combining, reacting, adding, dissolving, solubilizing, or any combination thereof.

As used herein, the term “silicon-containing film” refers to a film comprising at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. For example, the silicon-containing film may comprise at least one of a SiO film, a SiN film, a SiOC film, a SiCN film, a SiOCN film, or any combination thereof. In some embodiments, the silicon-containing film has a thickness of 20 Å to 2000 Å.

Some embodiments relate to disilylamine precursors and related methods. At least some of these embodiments relate to disilylamine precursors useful in the fabrication of microelectronic devices, including semiconductor devices, and the like. For example, the disilylamine precursors can be used to form silicon-containing films by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

Disilylamine precursors, such as, for example and without limitation, amino-silanes useful for thin film deposition are provided. The disilylamine precursors disclosed herein may be present in a liquid state at room temperature and atmospheric pressure. The disilylamine precursors disclosed herein may exhibit enhanced growth rate of atomic layer deposition SiO₂ relative to conventional precursors. The disilylamine precursors may not produce undesirable reaction byproducts and impurities. In some embodiments, the disilylamine precursors exhibit superior low temperature SiO₂ growth using plasma-enhanced atomic layer deposition processes and thermal atomic layer deposition processes. In addition, the disilylamine precursors are halogen free and high purity. The disilylamine precursors disclosed herein may be useful in the formation of high quality and high growth rate silicon-containing films, such as, for example and without limitation, SiO, SiN, SiOC, SiCN, SiOCN, and the like, at low temperatures.

In some embodiments, a precursor comprises a compound of the formula:

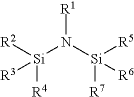

where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

In some embodiments, at least one of R¹, R², R³, R⁴, R⁵, R⁶, R⁷, or any combination thereof do not comprise silicon. In some embodiments, R¹ does not comprise silicon. In some embodiments, R² does not comprise silicon. In some embodiments, R³ does not comprise silicon. In some embodiments, R⁴ does not comprise silicon. In some embodiments, R⁵ does not comprise silicon. In some embodiments, R⁶ does not comprise silicon. In some embodiments, R⁷ does not comprise silicon.

In some embodiments, at least one of R², R³, R⁴, R⁵, R⁶, R⁷, or any combination thereof is not hydrogen. In some embodiments, R² is not hydrogen. In some embodiments, R³ is not hydrogen. In some embodiments, R⁴ is not hydrogen. In some embodiments, R⁵ is not hydrogen. In some embodiments, R⁶ is not hydrogen. In some embodiments, R⁷ is not hydrogen. In some embodiments, R², R³, and R⁴ are not hydrogen. In some embodiments, R⁵, R⁶, and R⁷ are not hydrogen.

In some embodiments, the precursor does not comprise a halide. In some embodiments, the precursor does not comprise at least one of F, Cl, Br, I, or any combination thereof.

In some embodiments, the precursor is present in a liquid phase at ambient temperature and ambient pressure. In some embodiments, the disilylamine precursor is a liquid at a temperature of 20° C.to 30° C. In some embodiments, the disilylamine precursor is a liquid at atmospheric pressure.

Examples of the precursor include, without limitation, compounds having at least one of the following structures:

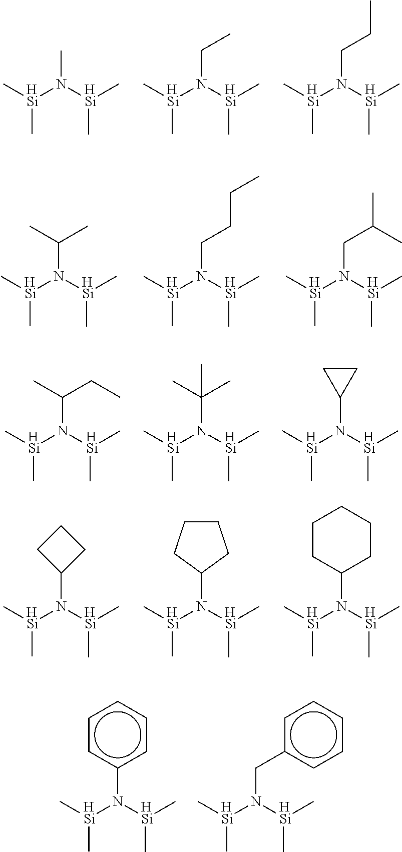

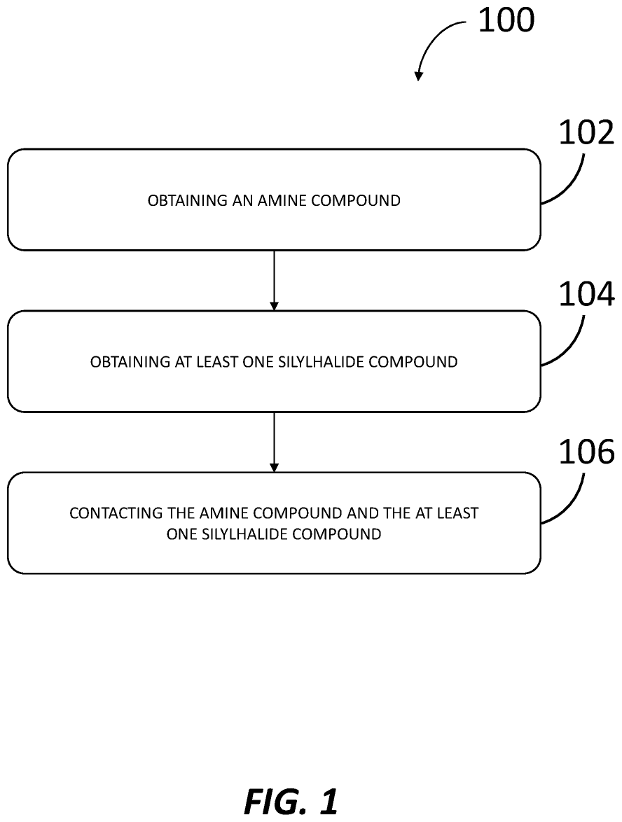

FIG. 1 is a flowchart of a method 100 for forming a precursor, according to some embodiments. In some embodiments, the method 100 is useful for forming any of the precursors disclosed herein. As shown in FIG. 1, the method for forming a precursor may comprise, consist of, or consist essentially of one or more of the following steps, in any order: a step 102 of obtaining an amine compound; a step 104 of obtaining at least one silylhalide compound; and a step 106 of contacting the amine compound and the at least one silylhalide compound, so as to form the precursor. In some embodiments, the method 100 may proceed entirely in a liquid phase. In some embodiments, the resulting precursor is a liquid. In some embodiments, the amine compound is a liquid. In some embodiments, the silylhalide compound is a liquid.

At step 102, in some embodiments, the method 100 comprises obtaining an amine compound. In some embodiments, the amine compound comprises a compound of the formula:

R¹—NH₂

where:
R¹ is an alkyl, an alkenyl, an alkynyl, a cycloalkyl, an aryl, or a benzyl.

In some embodiments, R¹ does not comprise silicon. In some embodiments, R¹ does not comprise a halide.

At step 104, in some embodiments, the method comprises obtaining at least one silylhalide compound. In some embodiments, the at least one silylhalide compound comprises a compound of the formula:

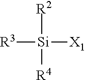

where:
X₁ is F, Cl, Br, or I;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl.

In some embodiments, at least one of R², R³, R⁴, or any combination thereof do not comprise silicon. In some embodiments, R² does not comprise silicon. In some embodiments, R³ does not comprise silicon. In some embodiments, R⁴ does not comprise silicon.

In some embodiments, at least one of R², R³, R⁴, or any combination thereof is not hydrogen. In some embodiments, R² is not hydrogen. In some embodiments, R³ is not hydrogen. In some embodiments, R⁴ is not hydrogen. In some embodiments, R², R³, and R⁴ are not hydrogen.

In some embodiments, the at least one silylhalide compound does not comprise a halide. In some embodiments, the at least one silylhalide compound does not comprise at least one of F, Cl, Br, I, or any combination thereof.

In some embodiments, the at least one silylhalide compound comprises a compound of the formula:

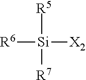

where:
X₂ is F, Cl, Br, or I;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

In some embodiments, at least one of R⁵, R⁶, R⁷, or any combination thereof do not comprise silicon. In some embodiments, R⁵ does not comprise silicon. In some embodiments, R⁶ does not comprise silicon. In some embodiments, R⁷ does not comprise silicon.

In some embodiments, at least one of R⁵, R⁶, R⁷, or any combination thereof is not hydrogen. In some embodiments, R⁵ is not hydrogen. In some embodiments, R⁶ is not hydrogen. In some embodiments, R⁷ is not hydrogen. In some embodiments, R⁵, R⁶, and R⁷ are not hydrogen.

In some embodiments, the at least one silylhalide compound does not comprise a halide. In some embodiments, the at least one silylhalide compound does not comprise at least one of F, CI, Br, I, or any combination thereof.

In some embodiments, a molar ratio of the amine compound to the silylhalide compound is at least 1:1. In some embodiments, the molar ratio of the amine compound to the silyl halide compound is a molar ratio of 1:1 to 1:10, or any range or subrange therebetween. In some embodiments, for example, the molar ratio of the amine compound to the silylhalide compound is a molar ratio 1:1 to 1:10, 1:1 to 1:9, 1:1 to 1:8, 1:1 to 1:7, 1:1 to 1:6, 1:1 to 1:5, 1:1 to 1:4, 1:1 to 1:3, or 1:1 to 1:2.

At step 106, in some embodiments, the method 100 comprises contacting the amine compound and the at least one silylhalide compound.

In some embodiments, the contacting comprises bringing into direct contact, or immediate or close proximity. In some embodiments, the contacting comprises combining or adding to a reaction flask, a reaction vial, or a reactor. In some embodiments, the contacting comprises at least one of dissolving, solubilizing, reacting, or stirring. In some embodiments, the contacting comprises adding dropwise.

In some embodiments, the amine compound is contacted with only one silylhalide compound. In some embodiments, the amine compound is contacted with two or more silylhalide compounds. In some embodiments, for example, the amine compound is contacted with a first silylhalide compound, so as to form an intermediate. In some embodiments, the intermediate is contacted with a second silylhalide compound so as to form the precursor. Any of the silylhalide compounds disclosed herein may be employed as the silylhalide compound, the first silylhalide compound, the second silylhalide compound, or any combination thereof, without departing from the scope of this disclosure.

In some embodiments, the first silylhalide compound comprises a compound of the formula:

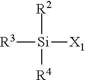

where:
X₁ is F, Cl, Br, or I;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl.

In some embodiments, at least one of R², R³, R⁴, or any combination thereof do not comprise silicon. In some embodiments, R² does not comprise silicon. In some embodiments, R³ does not comprise silicon. In some embodiments, R⁴ does not comprise silicon.

In some embodiments, at least one of R², R³, R⁴, or any combination thereof is not hydrogen. In some embodiments, R² is not hydrogen. In some embodiments, R³ is not hydrogen. In some embodiments, R⁴ is not hydrogen. In some embodiments, R², R³, and R⁴ are not hydrogen.

In some embodiments, the first silylhalide compound does not comprise a halide. In some embodiments, the first silylhalide compound does not comprise at least one of F, Cl, Br, I, or any combination thereof.

In some embodiments, the intermediate is a compound of the formula:

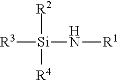

where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl.

In some embodiments, the second silylhalide compound comprises a compound of the formula:

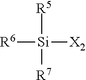

where:
X₂ is F, Cl, Br, or I;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

In some embodiments, at least one of R⁵, R⁶, R⁷, or any combination thereof do not comprise silicon. In some embodiments, R⁵ does not comprise silicon. In some embodiments, R⁶ does not comprise silicon. In some embodiments, R⁷ does not comprise silicon.

In some embodiments, at least one of R⁵, R⁶, R⁷, or any combination thereof is not hydrogen. In some embodiments, R⁵ is not hydrogen. In some embodiments, R⁶ is not hydrogen. In some embodiments, R⁷ is not hydrogen. In some embodiments, R⁵, R⁶, and R⁷ are not hydrogen.

In some embodiments, the second silylhalide compound does not comprise a halide. In some embodiments, the second silylhalide compound does not comprise at least one of F, Cl, Br, I, or any combination thereof.

In some embodiments, the precursor comprises a compound of the formula:

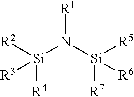

where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

In some embodiments, the contacting proceeds in a solvent. In some embodiments, the solvent comprises at least one of CH₂Cl₂, Et₂O, n-hexane, EtOAc, THF, or any combination thereof. In some embodiments, the contacting proceeds in a presence of an alkyllithium. In some embodiments, the alkyllithium comprises at least one of methyl lithium, n-butyl lithium, t-butyl lithium, or any combination thereof.

In some embodiments, the contacting is performed under heating at or to a temperature in a range of −50° C.to 50° C., or any range or subrange therebetween. In some embodiments, for example, the heating is performed at or to a temperature in a range of −50° C. to 45° C., −50° C. to 40° C., −50° C. to 35 ° C., −50° C. to 30° C., −50° C. to 25° C., —50° C. to 20° C., —50° C. to 15° C., —50° C. to 10° C., —50° C. to 5° C., −50 ° ° C. to 0 ° C., —50 ° C. to —5 ° C., —50 ° C. to —10 ° C., —50 ° C. to —15° C., —50° C. to —20° C., —50 ° C. to —25 ° C., —50 ° C. to —30 ° C., —50 ° C. to —35 ° C., —50 ° C. to —40° C., —50° C. to —45° ° C., —45 ° C. to 50 ° C., —40 ° ° C. to 50 ° C., —35 ° C. to 50 ° C., —30° C. to 50° ° C., —25° C. to 50° C., —20 ° ° C. to 50 ° C., —15 ° C. to 50 ° C., —10 ° ° C. to 50 ° C., —5° C. to 50° C., 0° C. to 50° C., 5 ° C. to 50 ° C., 10 ° ° C. to 50 ° C., 15 ° C. to 50 ° C., 20 ° C. to 50° C., 25° C. to 50° C., 30° C. to 50 ° C., 35 ° ° C. to 50 ° C., 40 ° C. to 50 ° C., or 45 ° C. to 50° C.

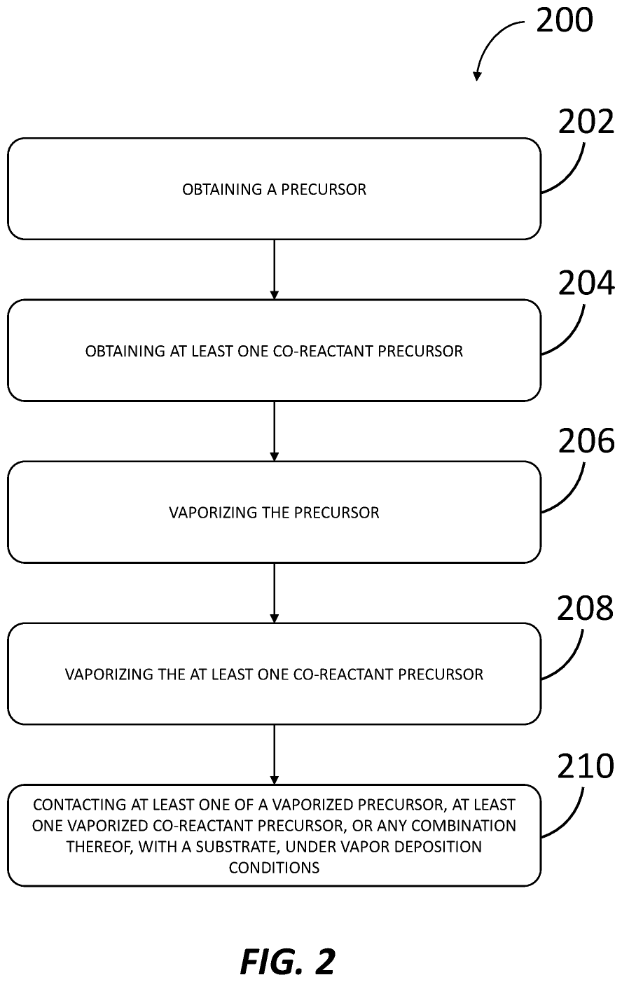

FIG. 2 is a flowchart of a method 200 for making a silicon-containing film, according to some embodiments. As shown in FIG. 2, the method 200 for making a silicon-containing film may comprise, consist of, or consist essentially of one or more of the following steps: obtaining 202 a precursor, obtaining 204 at least one co-reactant precursor, vaporizing 206 the precursor to obtain a vaporized precursor, vaporizing 208 the at least one co-reactant precursor to obtain at least one vaporized co-reactant precursor, contacting 210 at least one of the vaporized precursor, the at least one vaporized co-reactant precursor, or any combination thereof with a substrate, under vapor deposition conditions, to form a silicon-containing film on the substrate.

The step 202 may comprise, consist of, or consist essentially of obtaining a precursor. The precursor may comprise, consist of, or consist essentially of any one or more of the precursors disclosed herein. The obtaining may comprise obtaining a container or other vessel comprising the precursor. In some embodiments, the precursor may be obtained in a container or other vessel in which the precursor is to be vaporized.

The step 204 may comprise, consist of, or consist essentially of obtaining at least one co-reactant precursor. In some embodiments, the at least one co-reactant precursor comprises, consists of, or consists essentially of, or is selected from the group consisting of, at least one of an oxidizing gas, a reducing gas, a hydrocarbon, or any combination thereof. The at least one co-reactant precursor may be selected to obtain a desired silicon-containing film. In some embodiments, the at least one co-reactant precursor may comprise, consist of, or consist essentially of at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, or any combination thereof. In some embodiments, the at least one co-reactant precursor may comprise, consist of, or consist essentially of at least one of H₂, O₂, O₃, H₂O, H₂O₂, NO, N₂O, NO₂, CO, CO₂, a carboxylic acid, an alcohol, a diol, or any combination thereof. In some embodiments, the at least one co-reactant precursor comprise, consist of, or consist essentially of at least one of methane, ethane, ethylene, acetylene, or any combination thereof. The obtaining may comprise obtaining a container or other vessel comprising the at least one co-reactant precursor. In some embodiments, the at least one co-reactant precursor may be obtained in a container or other vessel in which the at least one co-reactant precursor is to be vaporized. In some embodiments, the method further comprises an inert gas, such as, for example, at least one of argon, helium, nitrogen, or any combination thereof.

The step 206 may comprise, consist of, or consist essentially of vaporizing the precursor to obtain a vaporized precursor. The vaporizing may comprise, consist of, or consist essentially of heating the precursor sufficient to obtain the vaporized precursor. In some embodiments, the vaporizing may comprise, consist of, or consist essentially of heating a container comprising the precursor. In some embodiments, the vaporizing may comprise, consist of, or consist essentially of heating the precursor in a deposition chamber in which the vapor deposition process is performed. In some embodiments, the vaporizing may comprise, consist of, or consist essentially of heating a conduit for delivering the precursor, vaporized precursor, or any combination thereof to, for example, a deposition chamber. In some embodiments, the vaporizing may comprise, consist of, or consist essentially of operating a vapor delivery system comprising the precursor. In some embodiments, the vaporizing may comprise, consist of, or consist essentially of heating to a temperature sufficient to vaporize the precursor to obtain the vaporized precursor. In some embodiments, the vaporizing may comprise, consist of, or consist essentially of heating to a temperature below a decomposition temperature of at least one of the precursor, the vaporized precursor, or any combination thereof. In some embodiments, the precursor may be present in a gas phase, in which case the step 206 is optional and not required. For example, the precursor may comprise, consist of, or consist essentially of the vaporized precursor.

The step 208 may comprise, consist of, or consist essentially of vaporizing the at least one co-reactant precursor to obtain the at least one vaporized co-reactant precursor. In some embodiments, the vaporizing may comprise, consist of, or consist essentially of heating the at least one co-reactant precursor sufficient to obtain the at least one vaporized co-reactant precursor. In some embodiments, the vaporizing may comprise, consist of, or consist essentially of heating a container comprising the at least one co-reactant precursor. In some embodiments, the vaporizing may comprise, consist of, or consist essentially of heating the at least one co-reactant precursor in a deposition chamber in which the vapor deposition process is performed. In some embodiments, the vaporizing may comprise, consist of, or consist essentially of heating a conduit for delivering the at least one co-reactant precursor, the at least one vaporized co-reactant precursor, or any combination thereof to, for example, a deposition chamber. In some embodiments, the vaporizing may comprise, consist of, or consist essentially of operating a vapor delivery system comprising the at least one co-reactant precursor. In some embodiments, the vaporizing may comprise, consist of, or consist essentially of heating to a temperature sufficient to vaporize the at least one co-reactant precursor to obtain the at least one vaporized co-reactant precursor. In some embodiments, the vaporizing may comprise, consist of, or consist essentially of heating to a temperature below a decomposition temperature of at least one of the at least one co-reactant precursor, the at least one vaporized co-reactant precursor, or any combination thereof. In some embodiments, the at least one co-reactant precursor may be present in a gas phase, in which case the step 108 is optional and not required. For example, the at least one co-reactant precursor may comprise, consist of, or consist essentially of the at least one vaporized co-reactant precursor.

The step 210 may comprise, consist of, or consist essentially of contacting at least one of the vaporized precursor, the at least one vaporized co-reactant precursor, or any combination thereof, with the substrate, under vapor deposition conditions, sufficient to form a silicon-containing film on a surface of the substrate. The contacting may be performed in any system, apparatus, device, assembly, chamber thereof, or component thereof suitable for vapor deposition processes, including, for example and without limitation, a deposition chamber, among others. The vaporized precursor and the at least one co-reactant precursor may be contacted with the substrate at the same time or at different times. For example, each of the vaporized precursor, the at least one vaporized co-reactant precursor, and the substrate may be present in the deposition chamber at the same time. That is, in some embodiments, the contacting may comprise contemporaneous contacting or simultaneous contacting of the vaporized precursor and the at least one vaporized co-reactant precursor with the substrate. Alternatively, each of the vaporized precursor and the at least one vaporized co-reactant precursor may be present in the deposition chamber at different times. That is, in some embodiments, the contacting may comprise alternate and/or sequential contacting, in one or more cycles, of the vaporized precursor with the substrate and subsequently contacting the at least one vaporized co-reactant precursor with the substrate.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise, consist of, or consist essentially of a deposition temperature. The deposition temperature may be a temperature less than the thermal decomposition temperature of at least one of the vaporized precursor, the at least one vaporized co-reactant precursor, or any combination thereof. The deposition temperature may be sufficiently high to reduce or avoid condensation of at least one of the vaporized precursor, the at least one vaporized precursor, or any combination thereof. In some embodiments, the substrate may be heated to the deposition temperature. In some embodiments, the chamber or other vessel in which the substrate is contacted with the vaporized precursor and the at least one vaporized co-reactant precursor is heated to the deposition temperature. In some embodiments, at least one of the vaporized precursor, the at least one vaporized co-reactant precursor, or any combination thereof may be heated to the deposition temperature.

The deposition temperature may be a temperature of 200° C.to 2500° C. In some embodiments, the deposition temperature may be a temperature of 500° C. to 700° C. For example, in some embodiments, the deposition temperature may be a temperature of 500° C.to 680° C., 500° C.to 660° C., 500° C.to 640° C., 500° C.to 620° C., 500° C.to 600° C., 500° C.to 580° C., 500° C.to 560° C., 500° C.to 540° C., 500° C.to 520° C., 520° C.to 700° C., 540° C.to 700° C., 560° C.to 700° C., 580° C.to 700° C., 600° C. to 700° C., 620° C.to 700° C., 640° C.to 700° C., 660° C.to 700° C., or 680° C.to 700° C. In other embodiments, the deposition temperature may be a temperature of greater than 200° C. to 2500° C., such as, for example and without limitation, a temperature of 400° C.to 2000, 500° C.to 2000° C., 550° C.to 2400° C., 600° C.to 2400° C., 625° C.to 2400° C., 650° C.to 2400° C., 675° C.to 2400° C., 700° C.to 2400° C., 725° C. to 2400° C., 750° C.to 2400° C., 775° C.to 2400° C., 800° C.to 2400° C., 825° C.to 2400° C., 850° C.to 2400° C., 875° C.to 2400° C., 900° C.to 2400° C., 925° C.to 2400° C., 950° C. to 2400° C., 975° C.to 2400° C., 1000° C.to 2400° C., 1025° C.to 2400° C., 1050° C. to 2400° C., 1075° C.to 2400° C., 1100° C.to 2400° C., 1200° C.to 2400° C., 1300° C. to 2400° C., 1400° C.to 2400° C., 1500° C.to 2400° C., 1600° C.to 2400° C., 1700° C.to 2400° C., 1800° C.to 2400° C., 1900° C.to 2400° C., 2000° C.to 2400° C., 2100° C.to 2400° C., 2200° C.to 2400° C., 2300° C.to 2400° C., 500° C.to 2000° C., 500° C.to 1900° C., 500° C.to 1800° C., 500° C.to 1700° C., 500° C.to 1600° C., 500° C.to 1500° C., 500° C. to 1400° C., 500° C.to 1300° C., 500° C.to 1200° C., 500° C.to 1100° C., 500° C.to 1000° C., 500° C.to 1000° C., 500° C.to 900° C., or 500° C.to 800° C.

The vapor deposition conditions may comprise, consist of, or consist essentially of a deposition pressure. In some embodiments, the deposition pressure may comprise, consist of, or consist essentially of a vapor pressure of at least one of the vaporized precursor, the at least one vaporized co-reactant precursor, or any combination thereof. In some embodiments, the deposition pressure may comprise, consist of, or consist essentially of a chamber pressure.

The deposition pressure may be a pressure of 0.001 Torr to 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

The substrate may comprise, consist of, or consist essentially of at least one of Si, Co, Cu, Al, W, WN, WC, TiN, Mo, MoC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof. In some embodiments, the silicon-containing film may comprise, consist of, or consist essentially of at least one of at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. In some embodiments, the substrate may comprise other silicon-based substrates, such as, for example, one or more of polysilicon substrates, metallic substrates, and dielectric substrates.

Some embodiments relate to a silicon-containing film on a surface of a substrate. In some embodiments, the silicon-containing film comprises any film formed according to the methods disclosed herein. In some embodiments, the silicon-containing film comprises any film prepared from the precursors disclosed herein.

### EXAMPLE 1

### Synthesis of Bis(dimethylsilyl)cyclohexylamine

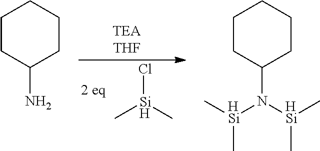

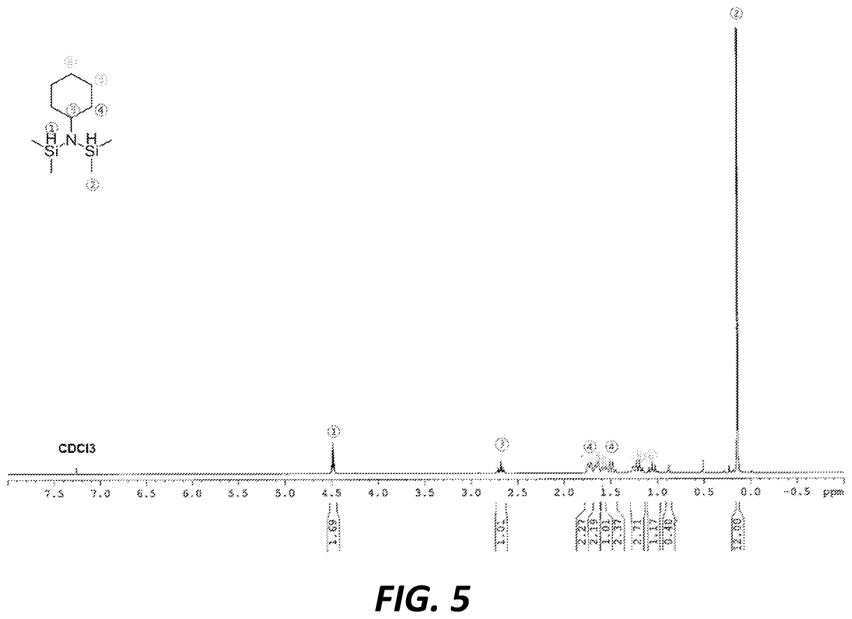

To (CH₃)₂SiHCl (35.2 g, 0.37 mol) in THF was added a triethylamine (38.6 g, 0.381 mol) under 30° C. As soon as the injection, a vapor was generated inside the reactor and the mixture turned cloudy. After 30 minutes of reaction time, cyclohexylamine (18.0 g, 0.182 mol) was added to the mixture. After 7 days of reaction time at room temperature, the mixture was filtered by glass filter and was rinsed with THF. Conversion of cyclohexylamine to precursor was determined by analysis of the GC-FID of the reaction mixture, and the distribution of GC-FID was almost 97% one peak with less than 3% impurities. The volatiles were removed in a distillation system at 200 Torr to 300 Torr and an internal temperature of 35-50° C. The product was distilled at 30° C.to 40° C., at 0.8 Torr to 1 Torr to afford 16.08 g of the precursor in 41% yield. The main product was confirmed by ¹H NMR spectroscopy (FIG. 5).

### EXAMPLE 2

### Synthesis of Bis(dimethylsilyl)(t-butyl)amine

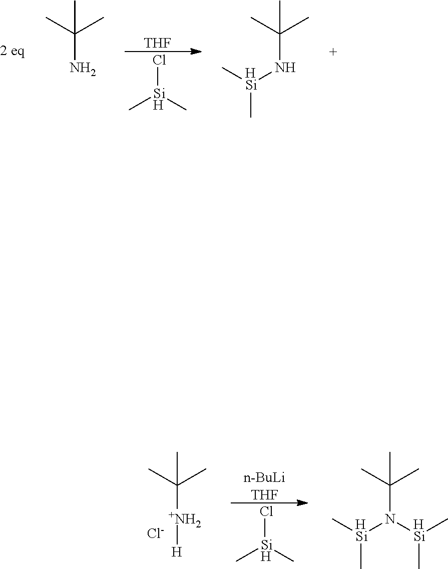

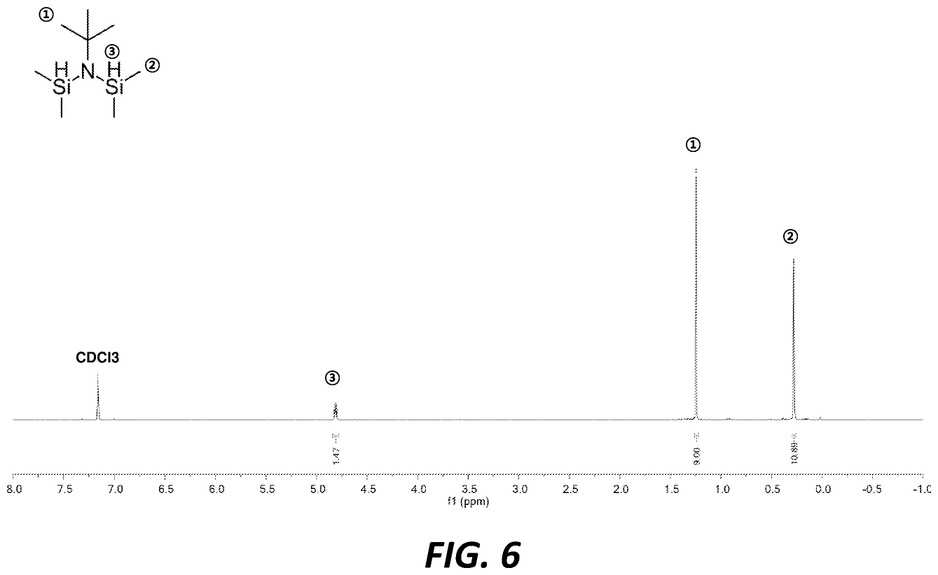

(CH₃)₂SiHCl (53.0 g, 0.56 mol) in THF was cooled down to −40° C.and was stirred for 30 minutes. To the mixture was added tert-butylamine (81.9 g, 1.12 mol), and the mixture was stirred overnight without cooling. The mixture was filtered by glass filter and was rinsed with THF. To the filtered mixture was added a 2.5 M solution of n-BuLi (224.1 ml, 0.56 mol) at 0° C., which was stirred overnight without cooling. To the mixture was added (CH₃)₂SiHCl (53.0 g, 0.56 mol) at 0° C., which was stirred overnight. The mixture was filtered by glass filter and the volatiles were removed, at 200 Torr to 300 Torr and an internal temperature of 30° C.to 35° C. The concentrated mixture was filtered by glass filter, and n-hex was added to remove impurities. The mixture was filtered by a glass filter, and the volatiles were removed in a distillation system at 200 Torr to 300 Torr and an internal temperature of 30° ° C.to 35° C. The product was distilled at 40° C.to 45° C., at 10 Torr to 15 Torr to afford 53.8 g of the precursor in overall 50.7% yield. The main product was confirmed by ¹H NMR spectroscopy (FIG. 6).

### EXAMPLE 3

### Synthesis of Bis(dimethylsilyl)(isopropyl)amine

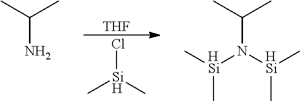

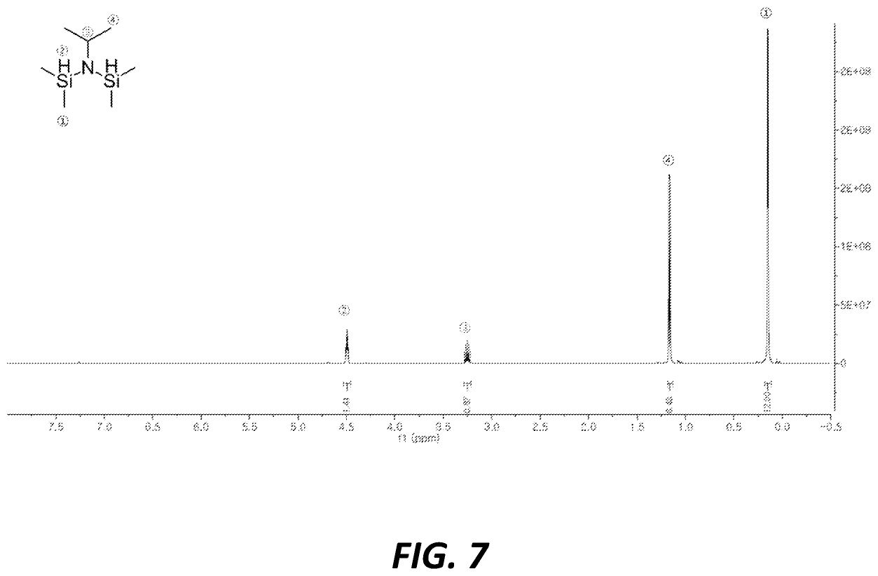

To (CH₃)₂SiHCl (43.7 g, 0.46 mol) in THF was added an iso-propylamine (26 g, 0.44 mol) under 30° C., and mixture was stirred overnight. As soon as the injection, a vapor was generated inside the reactor and the mixture turned cloudy. The mixture was filtered by a glass filter and was rinsed with THF. Conversion of iso-propylamine to the precursor was determined by analysis of the GC-FID of the reaction mixture, and the distribution of GC-FID was almost 99% one peak with less than 1% impurities. The volatiles were removed in a distillation system at 100 Torr to 200 Torr and an internal temperature of 30° C.to 40° C. The product was distilled at 30° C.to 35° C., at 5 Torr to 10 Torr to afford 33.19 g of the precursor in 44% yield. The main product was confirmed by ¹H NMR spectroscopy (FIG. 7).

### EXAMPLE 4

### Synthesis of N-Ethylbis(dimethylsilyl)amine

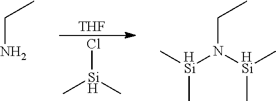

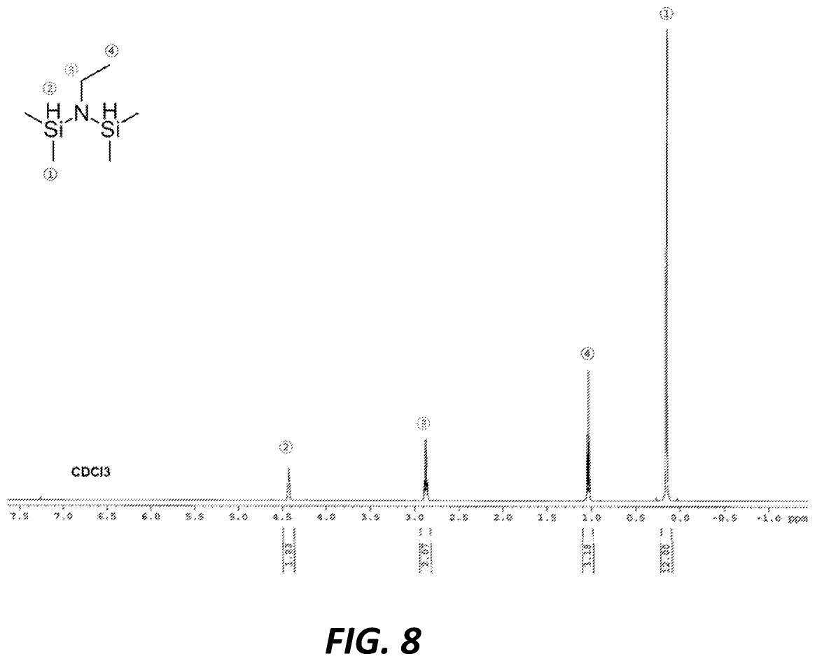

To (CH₃)₂SiHCl (39.74 g, 0.42 mol) in THF was added ethylamine (8.2 g, 0.182 mol) under 30° C., and the mixture was stirred overnight. As soon as the injection, a vapor was generated inside the reactor and the mixture turned cloudy. After 1 day of reaction time at room temperature, the mixture was filtered by a glass filter and rinsed with THF. Conversion of ethylamine to the precursor was determined by analysis of the GC-FID of the reaction mixture, and the distribution of GC-FID was almost 98% one peak with less than 2% impurities. The volatiles were removed in a distillation system at 150 Torr to 200 Torr and an internal temperature of 35° C.to 40° C. The product was distilled at 25° C.to 28° C., at 8 Torr to 10 Torr to afford 17. 2 g of precursor in 53.4% yield. The main product was confirmed by ¹H NMR spectroscopy (FIG. 8).

### Aspects

Various Aspects are described below. It is to be understood that any one or more of the features recited in the following Aspect(s) can be combined with any one or more other Aspect(s).
Aspect 1. A precursor comprising:
   a compound of the formula:

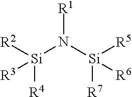

where:
   R¹ is an alkyl, an alkenyl, an alkynyl, a cycloalkyl, an aryl, or a benzyl;
   R² is a hydrogen, an alkyl, an alkenyl, an alkynyl, a cycloalkyl, an aryl, or a benzyl;
   R³ is a hydrogen, an alkyl, an alkenyl, an alkynyl, a cycloalkyl, an aryl, or a benzyl;
   R⁴ is a hydrogen, an alkyl, an alkenyl, an alkynyl, a cycloalkyl, an aryl, or a benzyl;
   R⁵ is a hydrogen, an alkyl, an alkenyl, an alkynyl, a cycloalkyl, an aryl, or a benzyl;
   R⁶ is a hydrogen, an alkyl, an alkenyl, an alkynyl, a cycloalkyl, an aryl, or a benzyl;
   R⁷ is a hydrogen, an alkyl, an alkenyl, an alkynyl, a cycloalkyl, an aryl, or a benzyl.
Aspect 2. The precursor according to Aspect 1, wherein R¹ is an alkyl.
Aspect 3. The precursor according to any one of Aspects 1-2, wherein R¹ is a linear C₁-C₄ alkyl.
Aspect 4. The precursor according to any one of Aspects 1-3, wherein R¹ is a branched C₃-C₄ alkyl.
Aspect 5. The precursor according to any one of Aspects 1-4, wherein R¹ is a cycloalkyl.
Aspect 6. The precursor according to any one of Aspects 1-5, wherein R¹ is a C₃-C₆ cycloalkyl.
Aspect 7. The precursor according to any one of Aspects 1-6, wherein R¹ is an aryl.
Aspect 8. The precursor according to any one of Aspects 1-7, wherein R¹ is a benzyl.
Aspect 9. The precursor according to any one of Aspects 1-8, wherein R¹ does not comprise silicon.
Aspect 10. The precursor according to any one of Aspects 1-9, wherein R², R³, R⁴, R⁵, R⁶, and R⁷ do not comprise silicon.
Aspect 11. The precursor according to any one of Aspects 1-10, wherein the precursor does not comprise a halide.
Aspect 12. The precursor according to any one of Aspects 1-11, wherein the precursor is present in a liquid phase at ambient temperature and ambient pressure.
Aspect 13. The precursor according to any one of Aspects 1-12, wherein the precursor comprises at least one of the following compounds:

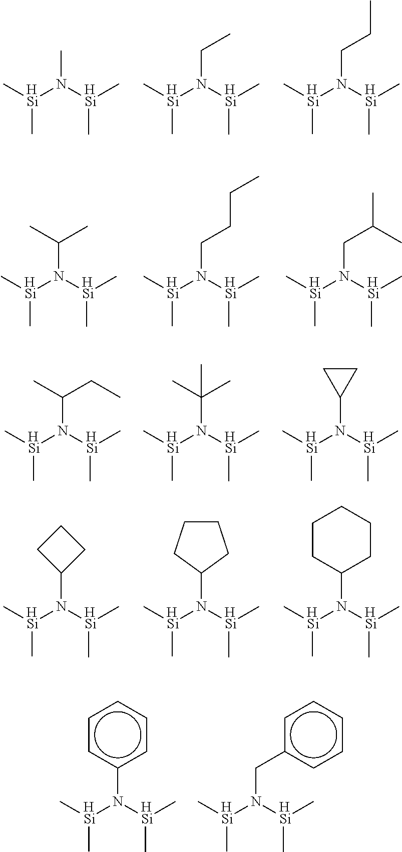

or any combination thereof.
Aspect 14. A method for forming a precursor, the method comprising:
   obtaining an amine compound;
   obtaining at least one silylhalide compound;
   contacting the amine compound and the at least one silylhalide compound, so as to form the precursor,
      wherein the precursor is a compound of the formula:

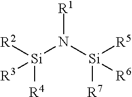

where:
   R¹ is an alkyl, an alkenyl, an alkynyl, a cycloalkyl, an aryl, or a benzyl;
   R² is a hydrogen, an alkyl, an alkenyl, an alkynyl, a cycloalkyl, an aryl, or a benzyl;
   R³ is a hydrogen, an alkyl, an alkenyl, an alkynyl, a cycloalkyl, an aryl, or a benzyl;
   R⁴ is a hydrogen, an alkyl, an alkenyl, an alkynyl, a cycloalkyl, an aryl, or a benzyl;
   R⁵ is a hydrogen, an alkyl, an alkenyl, an alkynyl, a cycloalkyl, an aryl, or a benzyl;
   R⁶ is a hydrogen, an alkyl, an alkenyl, an alkynyl, a cycloalkyl, an aryl, or a benzyl;
   R⁷ is a hydrogen, an alkyl, an alkenyl, an alkynyl, a cycloalkyl, an aryl, or a benzyl.
Aspect 15. The method according to Aspect 14, wherein the amine compound is a compound of the formula:

R¹—NH₂
where:
   R¹ is an alkyl, an alkenyl, an alkynyl, a cycloalkyl, an aryl, or a benzyl.
Aspect 16. The method according to any one of Aspects 14-15, wherein the at least one silylhalide compound is a compound of the formula:

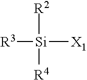

where:
   X₁ is F, Cl, Br, or I;
   R² is a hydrogen, an alkyl, an alkenyl, an alkynyl, a cycloalkyl, an aryl, or a benzyl;
   R³ is a hydrogen, an alkyl, an alkenyl, an alkynyl, a cycloalkyl, an aryl, or a benzyl;
   R⁴ is a hydrogen, an alkyl, an alkenyl, an alkynyl, a cycloalkyl, an aryl, or a benzyl.
17. The method according to any one of Aspects 14-16, wherein the at least one silylhalide compound is a compound of the formula:

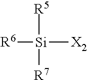

where:
   X₂ is F, Cl, Br, or I;
   R⁵ is a hydrogen, an alkyl, an alkenyl, an alkynyl, a cycloalkyl, an aryl, or a benzyl;
   R⁶ is a hydrogen, an alkyl, an alkenyl, an alkynyl, a cycloalkyl, an aryl, or a benzyl;
   R⁷ is a hydrogen, an alkyl, an alkenyl, an alkynyl, a cycloalkyl, an aryl, or a benzyl.
Aspect 18. The method according to any one of Aspects 14-17, wherein a molar ratio of the amine compound to the at least one silylhalide compound is at least 1:1.
Aspect 19. The method according to any one of Aspects 14-18, wherein a molar ratio of the amine compound to the at least one silylhalide compound is at least 1:2.
Aspect 20. The method according to any one of Aspects 14-19, wherein the contacting comprises:
   contacting the amine compound and a first silylhalide compound, so as to form an intermediate; and
   contacting the intermediate and a second silylhalide compound, so as to from the precursor;
      wherein the intermediate is a compound of the formula:

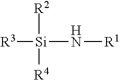

where:
   R¹ is an alkyl, an alkenyl, an alkynyl, a cycloalkyl, an aryl, or a benzyl;
   R² is a hydrogen, an alkyl, an alkenyl, an alkynyl, a cycloalkyl, an aryl, or a benzyl;
   R³ is a hydrogen, an alkyl, an alkenyl, an alkynyl, a cycloalkyl, an aryl, or a benzyl;
   R⁴ is a hydrogen, an alkyl, an alkenyl, an alkynyl, a cycloalkyl, an aryl, or a benzyl.
Aspect 21. The method according to any one of Aspects 14-20, wherein the contacting comprises contacting in a solvent, wherein the solvent comprises at least one of CH₂Cl₂, Et₂O, n-hexane, EtOAc, THF, or any combination thereof.
Aspect 22. The method according to any one of Aspects 14-21, wherein the contacting comprises contacting in a presence of an alkyllithium.
Aspect 23. The method according to Aspect 22, wherein the alkyllithium comprises at least one of methyl lithium, n-butyl lithium, t-butyl lithium, or any combination thereof.
Aspect 24. The method according to any one of Aspects 14-23, wherein R¹ does not comprise silicon.
Aspect 25. The method according to any one of Aspects 14-24, wherein R², R³, R⁴, R⁵, R⁶, and R⁷ do not comprise silicon.
Aspect 26. The method according to any one of Aspects 14-25, wherein the amine compound and silylhalide compound are present in a liquid phase.
Aspect 27. A method for vapor deposition comprising:
   obtaining a precursor, wherein the precursor comprises a compound of the formula:

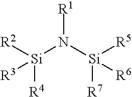

where:
   R¹ is an alkyl, an alkenyl, an alkynyl, a cycloalkyl, an aryl, or a benzyl;
   R² is a hydrogen, an alkyl, an alkenyl, an alkynyl, a cycloalkyl, an aryl, or a benzyl;
   R³ is a hydrogen, an alkyl, an alkenyl, an alkynyl, a cycloalkyl, an aryl, or a benzyl;
   R⁴ is a hydrogen, an alkyl, an alkenyl, an alkynyl, a cycloalkyl, an aryl, or a benzyl;
   R⁵ is a hydrogen, an alkyl, an alkenyl, an alkynyl, a cycloalkyl, an aryl, or a benzyl;
   R⁶ is a hydrogen, an alkyl, an alkenyl, an alkynyl, a cycloalkyl, an aryl, or a benzyl;
   R⁷ is a hydrogen, an alkyl, an alkenyl, an alkynyl, a cycloalkyl, an aryl, or a benzyl;
vaporizing the precursor to obtain a vaporized precursor; and
contacting the vaporized precursor with a substrate, under vapor deposition conditions, so as to form a silicon-containing film on the substrate.
Aspect 28. The method according to Aspect 27, wherein the vapor deposition conditions comprise plasma-enhanced atomic layer deposition conditions.
Aspect 29. The method according to any one of Aspects 27-28, wherein the vapor deposition conditions comprise thermal atomic layer deposition conditions.
Aspect 30. The method according to any one of Aspects 27-29, wherein the silicon-containing film comprises at least one of SiO, SiN, SiOC, SiCN, SiOCN, or any combination thereof.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A precursor comprising:
a compound of the formula: 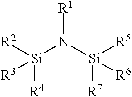
where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

2. The precursor of claim 1, wherein R¹ is an alkyl.

3. The precursor of claim 1, wherein R¹ is a linear C₁-C₄ alkyl.

4. The precursor of claim 1, wherein R¹ is a branched C₃-C₄ alkyl.

5. The precursor of claim 1, wherein R¹ is a cycloalkyl.

6. The precursor of claim 1, wherein R¹ is a C₃-C₆ cycloalkyl.

7. The precursor of claim 1, wherein R¹ is an aryl.

8. The precursor of claim 1, wherein R¹ is a benzyl.

9. The precursor of claim 1, wherein R¹ does not comprise silicon.

10. The precursor of claim 1, wherein the precursor comprises at least one of the following compounds: 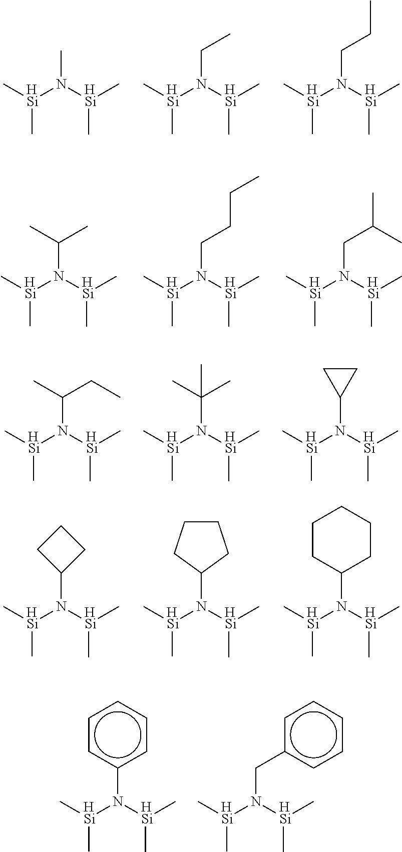
or any combination thereof.

11. A method for forming a precursor, the method comprising:
obtaining an amine compound;
obtaining at least one silylhalide compound;
contacting the amine compound and the at least one silylhalide compound, so as to form the precursor,
wherein the precursor is a compound of the formula: 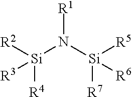
where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

12. The method of claim 11, wherein the amine compound is a compound of the formula:
R¹—NH₂
where:
R¹ is an alkyl, an alkenyl, an alkynyl, a cycloalkyl, an aryl, or a benzyl.

13. The method of claim 11, wherein the at least one silylhalide compound is a compound of the formula: 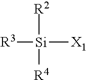
where:
X₁ is F, Cl, Br, or I;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl.

14. The method of claim 11, wherein the at least one silylhalide compound is a compound of the formula: 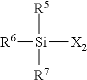
where:
X₂ is F, Cl, Br, or I;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl.

15. The method of claim 11, wherein a molar ratio of the amine compound to the at least one silylhalide compound is at least 1:1.

16. The method of claim 11, wherein a molar ratio of the amine compound to the at least one silylhalide compound is at least 1:2.

17. The method of claim 11, wherein the contacting comprises:
contacting the amine compound and a first silylhalide compound, so as to form an intermediate; and
contacting the intermediate and a second silylhalide compound, so as to from the precursor;
wherein the intermediate is a compound of the formula: 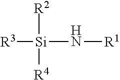
where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl.

18. The method of claim 11 wherein the contacting comprises contacting in a solvent, wherein the solvent comprises at least one of CH₂Cl₂, Et₂O, n-hexane, EtOAc, THF, or any combination thereof.

19. A method for vapor deposition comprising:
obtaining a precursor, wherein the precursor comprises a compound of the formula: 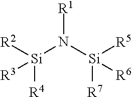
where:
R¹ is an alkyl, an alkenyl, an alkynyl, a cycloalkyl, an aryl, or a benzyl;
R² is a hydrogen, an alkyl, an alkenyl, an alkynyl, a cycloalkyl, an aryl, or a benzyl;
R³ is a hydrogen, an alkyl, an alkenyl, an alkynyl, a cycloalkyl, an aryl, or a benzyl;
R⁴ is a hydrogen, an alkyl, an alkenyl, an alkynyl, a cycloalkyl, an aryl, or a benzyl;
R⁵ is a hydrogen, an alkyl, an alkenyl, an alkynyl, a cycloalkyl, an aryl, or a benzyl;
R⁶ is a hydrogen, an alkyl, an alkenyl, an alkynyl, a cycloalkyl, an aryl, or a benzyl;
R⁷ is a hydrogen, an alkyl, an alkenyl, an alkynyl, a cycloalkyl, an aryl, or a benzyl;
vaporizing the precursor to obtain a vaporized precursor; and
contacting the vaporized precursor with a substrate, under vapor deposition conditions, so as to form a silicon-containing film on the substrate.

20. The method of claim 19, wherein the vapor deposition conditions comprise plasma-enhanced atomic layer deposition conditions.
